(19) United States
(12) Patent Application Publication
(10) Pub. No.: US 2008/0174011 A1
(43) Pub. Date: Jul. 24, 2008

(54) Semiconductor structure and method for forming the same

(75) Inventor: Wen-Yung Fu, Taiwan (TW)

Correspondence Address: BIRCH STEWART KOLASCH & BIRCH, PO BOX 747, FALLS CHURCH, VA, 22040-0747, US

(73) Assignee: CHIPMOS TECHNOLOGIES INC.

(21) Appl. No.: 11/907,276

(22) Filed: Oct. 10, 2007

(30) Foreign Application Priority Data
Jan. 24, 2007 (TW) 096102740

(51) Int. Cl. H01L 23/488; H01L 21/44

(52) U.S. Cl. 257/737; 438/613

(57) ABSTRACT

A semiconductor structure and a method for forming the same are provided. The semiconductor structure comprises a substrate and an integrated circuit laid on the substrate. A barrier layer is formed to provide a flattened surface, so that the under bump metal can be formed thereon. In this way, discontinuities, which would otherwise affect the impedance distribution, are avoided in the conductive layer, and thus, provide a stable conduction.

This application claims the benefit of priority based on Taiwan Patent Application No. 096102740 filed on Jan. 24, 2007, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to a conductive structure. More particularly, the present invention relates to a conductive structure for a semiconductor integrated circuit and a method for forming the same.

2. Descriptions of the Related Art

A number of bump electroplating technologies have been developed in the fields of microelectronics and micro systems. Such bump electroplating technologies are applicable to various stages of many processes, such as establishing a connection between a flat panel display and a driver IC, carrying out technologies for conductive lines and air bridges on a gallium arsenide chip, and fabricating X-ray masks when using LIGA technology.

For example, in connecting the circuit board to the IC, the IC may be connected with the circuit board in a variety of ways. Usually, the IC pads of the IC package can be electrically connected to the circuit board using bump (especially gold bump) electroplating technology. Such a technology not only substantially reduces the size of the ICs, but also allows them to be directly embedded into the circuit boards, thus, reducing the space, dissipating the heat and resulting in low induction. In addition, the low cost of the electroplating process has made bump electroplating technology a favorable development.

Typical bump electroplating processes, such as the gold bump electroplating process, require the preparation of an under bump metal on the pads, which serves not only as an adhesion layer between the bumps and the pads but also as a conductive medium subsequent to formation of the bumps. As a result, the bumps can be successfully formed on such an under bump and be electrically connected to the pads therethrough. For this reason, at least one conductive layer needs to be formed on the chip surface at locations other than the pads prior to the electroplating process and be removed by etching subsequent to the bump electroplating process.

However, in practice, the chip may have a rough surface. In this case, the conductive layer formed on such a rough surface tends to have nonconductive discontinuities or an uneven thickness, which may lead to increased electrical resistance of the conductive layer. As a response, in conventional technologies, the conductive layer and the under bump metal have been formed with a large average thickness to prevent the formation of discontinuities in the conductive layer. However, the increased thickness of the under bump metal or other conductive layers inevitably results in an increased equivalent resistance, and since the under bump metal between the bumps and the pads already has a relatively large resistance, a thicker under bump metal will result in increased resistance between the bumps and the pads. As a result, the electrical connection between the chip and the Circuit board is unfavorable. All these facts will adversely impact the electroplating effect, resulting in a lower yield of the bump electroplating process and a need for refinishing or completely discarding the resulting chip.

In view of these disadvantages, a technical breakthrough will be provided by the invention described below.

### SUMMARY OF THE INVENTION

One objective of this invention is to provide a semiconductor structure, which comprises a substrate and an integrated circuit laid on the substrate. A barrier layer is formed on the semiconductor structure to form a substantially flattened surface for the under bump metal to be formed thereon, thereby preventing an increased impedance and discontinuities. A semiconductor structure, comprising a passivation layer, a barrier layer and an under bump metal, is disclosed in this invention. The passivation layer is formed on the substrate, along with the integrated circuit to form a substantially non-flattened first upper surface. The barrier layer is formed on the passivation layer to form a substantially flattened second surface, and the under bump metal is in turn formed on the second surface of the barrier layer.

Also disclosed in this invention is a method for forming such a semiconductor structure, which comprises the following steps: forming a passivation layer with a substantially non-flattened first surface on a substrate where an integrated circuit is laid; planarizing the passivation layer by forming a barrier layer with a flattened second surface; and constructing a conductive interface for the electroplating process by forming an under bump metal on the second surface of the barrier layer.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1(a) to 1(d) depict a process flow for forming a semiconductor structure provided with a conductive structure in accordance with a preferred embodiment of this invention.

### DESCRIPTION OF THE PREFERRED EMBODIMENT

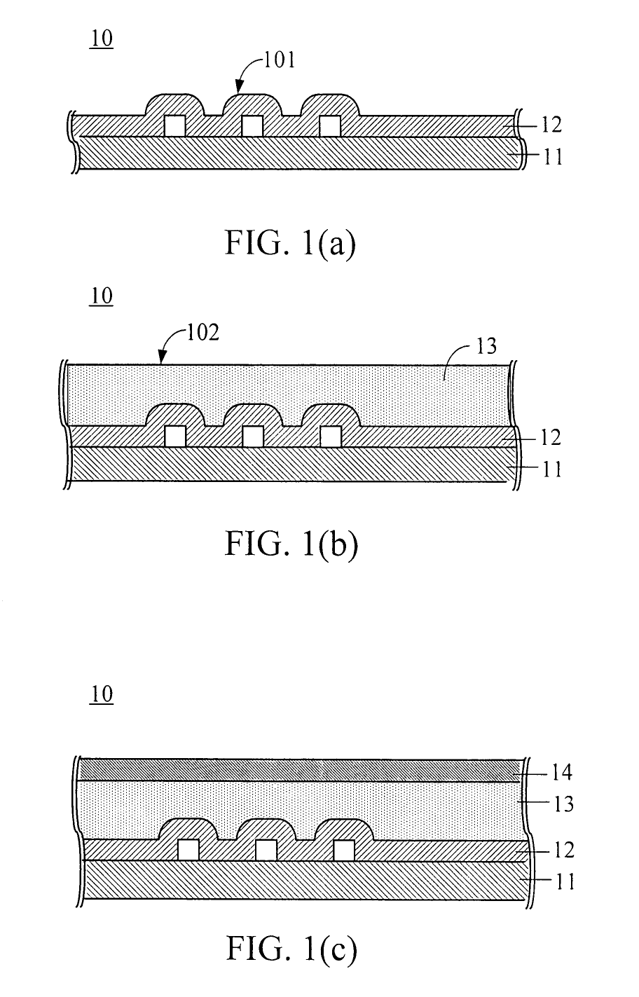

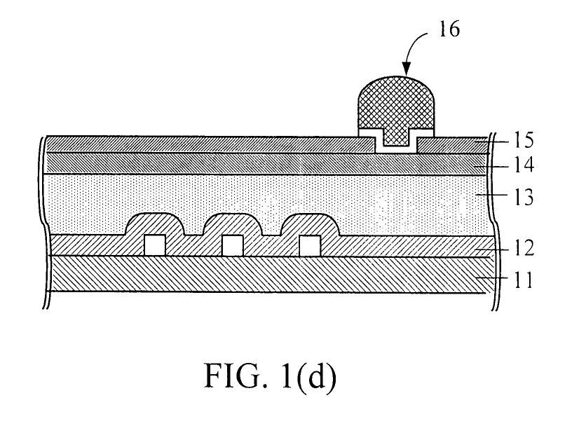

FIG. 1(a) to FIG. 1(d) depict a process flow for forming a semiconductor structure 10 provided with a conductive structure in accordance with a preferred embodiment of this invention.

As depicted in FIG. 1(a), the semiconductor structure 10 comprises a substrate 11 and a passivation layer 12 laid on the substrate 11. The integrated circuit layout arranged on the substrate 11 leads to a non-flattened surface of the passivation layer 12. As shown in this figure, the passivation layer 12 has a substantially non-flattened first upper surface 101, so if an under bump metal were formed directly on the first upper surface 101, discontinuities would appear in the under bump metal at the corners of the first upper surface 101, resulting in uneven impedance that represents poor conductive performance. However, since the passivation layer 12 has already been incorporated in the substrate 11 upon completion of the substrate 11 comprising the integrated circuit layout and is distributed isotropically throughout the substrate 11, it is impossible to form different passivation layers in accordance with the varied requirements of individual regions. Therefore, unevenness of the first upper surface 101 cannot be overcome by manipulating the forming process of the passivation layer 12.

As a result, this invention first provides a barrier layer that is formed on the first upper surface 101, such as a polyimide (PI) layer 13 with insulation characteristics. Consequently, the formation of the barrier layer on the first upper surface 101 will result in a certain thickness for the P1 layer 13. The barrier layer also forms a substantially flattened second surface 102, as shown in FIG. 1(b). Alternatively, the barrier layer may also be made of other materials with insulation properties, for example, oxides such as silicon dioxide. Subsequently, an under bump metal 14, which is made of a titanium/tungsten alloy in this embodiment, is formed on the P1 layer 13, as shown in FIG. 1(c). Since the P1 layer 13 is adapted to fill in the uneven portions of the first upper surface 101 and serves as insulation, the second surface 102 formed by the PI layer becomes flattened, so that the under bump metal 14 can be formed continuously on the second surface 102 without any discontinuities. Furthermore, the under bump metal 14 can also be formed with a uniform thickness and be used as the conductive layer of a uniform thickness. Similarly, additional conductive layers with the same or different material characteristics may be optionally added to render the conductivity more stable.

An overlay layer 15 is then formed on the under bump metal 14, and a bump 16 is formed in the predetermined region, as shown in FIG. 1(d). The bump 16 may be formed in the predetermined region of the under bump metal 14 through the overlay layer 15 using the electroplating process.

It follows from the above disclosures that, by forming an additional barrier layer 13 over the passivation layer 12, the semiconductor structure 10 of this invention can avoid discontinuities in the under bump metal 14, thereby, providing a stable conductive performance during the electroplating process. Meanwhile, such a design eliminates the need to substantially increase the thickness of the under bump metal 14 on account of possible discontinuities, so that the electrical impedance incurred in the bump 16 and the counterpart portions is substantially decreased.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A semiconductor structure comprising:
a substrate;
an integrated circuit being laid on the substrate;
a passivation layer being formed on the substrate provided with the integrated circuit to form a substantially non-flattened first upper surface;
a barrier layer being formed on the passivation layer to form a substantially flattened second surface; and
an under bump metal being formed on the second surface of the barrier layer.

2. The semiconductor structure as claimed in claim 1, further comprising a bump being formed on the under bump metal.

3. The semiconductor structure as claimed in claim 1, wherein the barrier layer is made of material comprising Polyimide (PI).

4. The semiconductor structure as claimed in claim 1, wherein the barrier layer is made of material comprising oxide.

5. The semiconductor structure as claimed in claim 1, wherein the under bump metal is made of titanium/tungsten alloy.

6. A method for forming a semiconductor structure, comprising the steps of:
forming a passivation layer having a substantially non-flattened first surface on a substrate where an integrated circuit is laid;
planarizing the passivation layer by forming a barrier layer having a substantially flattened second surface; and
construing a conductive interface for an electroplating process by forming an under bump metal on the second surface of the barrier layer.

7. The method as claimed in claim 6, wherein after the step pf construing the conductive interface, the method further comprises a step of forming a conductive structure by electroplating a bump onto the under bump metal.
